(19) United States
(12) Patent Application Publication
(10) Pub. No.: US 2012/0249187 A1
(43) Pub. Date: Oct. 4, 2012

(54) CURRENT SOURCE CIRCUIT

(76) Inventor: Noriyasu KUMAZAKI, Kawasaki-shi (JP)

(21) Appl. No.: 13/428,288

(22) Filed: Mar. 23, 2012

(30) Foreign Application Priority Data
Mar. 31, 2011 (JP) 2011-080382

(51) Int. Cl. H03B 21/00

(52) U.S. Cl. 327/105

(57) ABSTRACT

According to one embodiment, a current source circuit comprises a first circuit, a second circuit, and a current synthesizing circuit. The first circuit generates a first current having a positive temperature characteristic. The second circuit includes a feedback circuit configured to receive a first voltage having a negative temperature characteristic, and output a second voltage equal to the first voltage, and generates a second current having the negative temperature characteristic based on the second voltage. The current synthesizing circuit generates a constant current having an arbitrary temperature characteristic by adding the first and second currents.

### CROSS-REFERENCE TO RELATED APPLICATIONS

This application is based upon and claims the benefit of priority from prior Japanese Patent Application No. 2011-080382, filed Mar. 31, 2011, the entire contents of which are incorporated herein by reference.

### FIELD

Embodiments described herein relate generally to a current source circuit.

### BACKGROUND

Recently, as mobile apparatuses such as cell phones spread, memories for use in these apparatuses are required to have a high operating speed and low current consumption. NAND flash memories are widely used as these memories.

A semiconductor integrated circuit including the above-mentioned NAND flash memory improves the circuit performance by using a constant current source and constant voltage source. Therefore, it is required to implement an accurate constant current source and accurate constant voltage source. The constant current source is used to, e.g., accurately generate a given delay time, and accurately generate various voltages.

### BRIEF DESCRIPTION OF THE DRAWINGS

FIG. 1 is a view showing a configuration example of a current source circuit according to the first embodiment;

FIG. 2A is a graph showing the relationship between the constant current value and temperature characteristic in a current source circuit according to a comparative example;

FIG. 2B is a graph showing the relationship between the constant current value and temperature characteristic in the current source circuit according to the first embodiment;

FIG. 3 is a view showing an application example of the current source circuit according to the first embodiment;

FIG. 4 is a view showing a configuration example of a current source circuit according to the second embodiment;

FIG. 5 is a view showing an application example of the current source circuit according to the second embodiment;

FIG. 6 is a view showing a configuration example of a current source circuit according to the third embodiment;

FIG. 7 is a view showing a configuration example of a current source circuit according to the fourth embodiment;

FIG. 8 is view showing a delay circuit using the constant current source according to each embodiment; and

FIG. 9 is a view showing a charging circuit using the constant current source according to each embodiment.

### DETAILED DESCRIPTION

In general, according to one embodiment, a current source circuit comprises a first current generating circuit, second current generating circuit, and current synthesizing circuit. The first current generating circuit includes a first current mirror circuit including PMOS transistors, and a second current mirror circuit including NMOS transistors, and generates a first current having a positive temperature characteristic. The second current generating circuit includes a feedback circuit configured to receive a first voltage depending on a threshold voltage of the NMOS transistors and having a negative temperature characteristic, and output a second voltage equal to the first voltage, and generates a second current having the negative temperature characteristic based on the second voltage. The current synthesizing circuit generates a constant current having an arbitrary temperature characteristic by adding the first and second currents.

Embodiments will be explained below with reference to the accompanying drawing. In the drawing, the same reference numerals and symbols denote the same parts. Note that the voltages of nodes VC, VC2, VIREF, VIP, VIC, VA, and VB will be explained as they are respectively abbreviated as voltages VC, VC2, VIREF, VIP, VIC, VA, and VB in some cases.

It will be understood that when an element is referred to as being “electrically connected to” or “connected to” another element, it can be not only directly connected but also connected to the other element or intervening elements may be present.

### First Embodiment

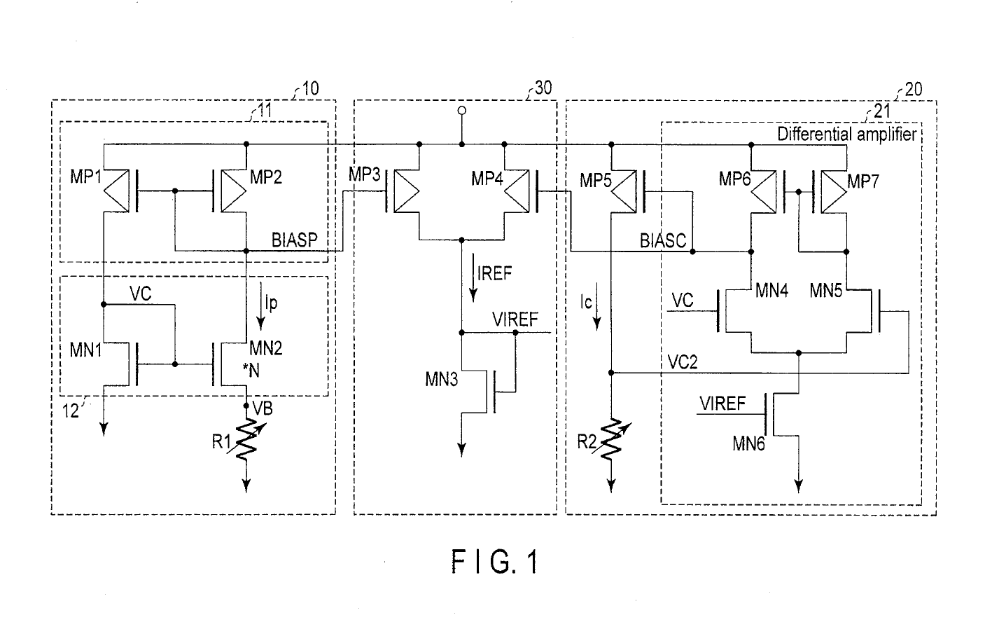

A semiconductor integrated circuit according to the first embodiment will be explained below with reference to FIGS. 1, 2A, 2B, and 3.

### [Circuit Configuration and Operation of First Embodiment]

FIG. 1 is a view showing a configuration example of a current source circuit according to the first embodiment.

As shown in FIG. 1, the current source circuit includes a first current generating circuit 10, second current generating circuit 20, and current synthesizing circuit 30.

The first current generating circuit 10 includes a first current mirror circuit 11, second current mirror circuit 12, and variable resistor R1.

The first current mirror circuit 11 includes PMOS transistors MP1 and MP2. More specifically, the sources of the PMOS transistors MP1 and MP2 are connected to the power supply. The gates of the PMOS transistors MP1 and MP2 are connected together to a node BIASP. The drain of the PMOS transistor MP1 is connected to a node VC (to be described later). The drain of the PMOS transistor MP2 is connected to the node BIASP to form a diode connection. That is, the potential difference between one end (the source) and the other end (the drain) of the current path of the PMOS transistor MP2 is equal to that between one end (the source) of the current path and the gate of the PMOS transistor MP2. Accordingly, the PMOS transistor MP2 operates as a pentode.

The second current mirror circuit 12 includes NMOS transistors MN1 and MN2 forming a current mirror. More specifically, the source of the NMOS transistor MN1 is connected to the ground potential. The source of the NMOS transistor MN2 is connected to one end of the variable resistor R1 via a node VB. The other end of the variable resistor R1 is connected to the ground potential. The gates of the NMOS transistors MN1 and MN2 are connected together to the node VC. The drain of the NMOS transistor MN2 is connected to the node BIASP. The drain of the NMOS transistor MN1 is connected to the node VC to form a diode connection. That is, the potential difference between one end (the source) and the other end (the drain) of the current path of the NMOS transistor MN1 is equal to that between one end (the source) of the current path and the gate of the NMOS transistor MN1. Therefore, the NMOS transistor MN1 operates as a pentode. Also, the number of NMOS transistors MN2 is N times that of NMOS transistors MN1, and the NMOS transistors MN2 are connected in parallel. In other words, the size of the NMOS transistor MN2 is N times that of the NMOS transistor MN1.

In the first current generating circuit 10 as described above, the current paths of the PMOS transistor MP1 and NMOS transistor MN1 are connected in series, and the current paths of the PMOS transistor MP2 and NMOS transistor MN2 and the variable resistor R1 are connected in series, between the power supply and ground potential.

When the voltage of the node BIASP exceeds a threshold voltage in the first current generating circuit 10, the PMOS transistors MP1 and MP2 are turned on, and a current flows through the node VC. Consequently, the node VC is boosted from the power supply via the PMOS transistors MP1 and MP2. When the voltage of the node VC exceeds a threshold voltage, the NMOS transistors MN1 and MN2 are turned on. Thus, a current flows through each transistor and each node.

As described above, the PMOS transistors MP1 and MP2 form a current mirror, and the NMOS transistors MN1 and MN2 form a current mirror. Therefore, a current Ip equal to that of the PMOS transistor MP2 and NMOS transistor MN2 flows through the PMOS transistor MP1 and NMOS transistor MN1. The current Ip is generated as follows.

Since the number of NMOS transistors MN2 is N times that of NMOS transistor MN1, a potential difference is produced between the gate-to-source potential of the NMOS transistor MN1 and that of the NMOS transistor MN2. This potential difference generates a voltage VB of the node VB. The current Ip is generated by applying the voltage VB to the variable resistor R1. The value of the current Ip is controlled by the variable resistor R1 and the number (size) of NMOS transistors MN2. In addition, the variable resistor R1 is adjusted for each chip in accordance the process variations (the power supply potential and the resistance and threshold value of each transistor). This makes it possible to generate, for each chip, the current Ip as a constant current independent of the process variations. The current IP generated as described above is represented by

$$Ip = \frac{2}{β {{R}^{2} ( \frac{\sqrt{N}}{\sqrt{N} - 1} )}^{2}} \qquad ( 1 )$$

where β is the mobility of electric charge. Since β has a negative temperature characteristic (β increases as the temperature decreases), the current Ip has a positive temperature characteristic (the current Ip increases as the temperature rises). Thus, the first current generating circuit 10 generates the current Ip having the positive temperature characteristic.

The second current generating circuit 20 includes a differential amplifier 21, PMOS transistor MP5, and variable resistor R2.

The differential amplifier 21 includes PMOS transistors MP6 and MP7 forming a current mirror, and NMOS transistors MN4, MN5, and MN6.

More specifically, the sources of the PMOS transistors MP6 and MP7 are connected to the power supply. The gates of the PMOS transistors MP6 and MP7 are connected together to the same node. The drain of the PMOS transistor MP6 is connected to a node BIASC as the output node of the differential amplifier 21. The drain of the PMOS transistor MP7 is connected together with its gate to the same node to form a diode connection. That is, the potential difference between one end (the source) and the other end (the drain) of the current path of the PMOS transistor MP7 is equal to that between one end (the source) of the current path and the gate of the PMOS transistor MP7. Therefore, the PMOS transistor MP7 operates as a pentode.

The sources of the NMOS transistors MN4 and MN5 are connected together to the same node as that of the drain of the NMOS transistor MN6, and the source of the NMOS transistor MN6 is grounded. The gate of the NMOS transistor MN4 is connected to the node VC of the first current generating circuit 10, which is the first input node of the differential amplifier 21. The gate of the NMOS transistor MN5 is connected to a node VC2 as the second input node of the differential amplifier 21.

The drain of the NMOS transistor MN4 is connected to the node BIASC. The drain of the NMOS transistor MN5 is connected together with the drain and gate of the PMOS transistor MP7 to the same node.

The source of the PMOS transistor MP5 is connected to the power supply. The gate of the PMOS transistor MP5 is connected to the node BIASC. The drain of the PMOS transistor MP5 is connected to the node VC2, and grounded via the variable resistor R2. In other words, the variable resistor R2 is connected between the node VC2 and ground potential. That is, the variable resistor R2 has one end connected to the node VC2, and the other end that is grounded.

The second current generating circuit 20 operates when the voltages of the node VC and a node VIREF (to be described later) exceed threshold voltages. In this state, the operating current of the differential amplifier 21 is determined by inputting a voltage VIREF of the node VIREF to the gate of the NMOS transistor MN6. When the voltages of the nodes VC and VIREF exceed the threshold voltages, the NMOS transistors MN4 and MN6 are turned on. Consequently, the voltage of the node BIASC exceeds the threshold voltage, and the PMOS transistor MP5 is turned on. Also, when a current Ic flows through the node VC2, the potential rises, and the NMOS transistor MN5 is turned on when the potential exceeds the threshold voltage. Furthermore, the PMOS transistors MP6 and MP7 are turned on when the voltages of their gates rise and exceed the threshold voltages. Thus, a current flows through each transistor and each node.

In this state, the current Ic flows through the PMOS transistor MP5 and variable resistor R2. The current Ic is generated as follows.

As described above, the voltage of the node VC of the first current generating circuit 10 is applied to the gate of the NMOS transistor MN4. Also, the PMOS transistors MP6 and MP7 form a current mirror. In this configuration, the node BIASC is controlled by making the PMOS transistors MP6 and PMOS transistors MP7 equal in size (number), and making the NMOS transistors MN4 and NMOS transistors MN5 equal in size (number), thereby generating a voltage VC2 equal to a voltage VC of the node VC. That is, the differential amplifier 21 functions as a feedback circuit that outputs the same voltage as an input voltage. In other words, the differential amplifier 21 functions as an amplifier having a gain of 1.

The node VC is the diode-connected node of the NMOS transistor MN1, and the voltage VC is represented by

$$VC = Vth + \sqrt{\frac{2 Ip}{β}} = VC 2 \qquad ( 2 )$$

where Vth is the threshold voltage of the NMOS transistor MN1. The threshold voltage Vth has the negative temperature characteristic. Accordingly, the voltage VC of the node VC and the voltage VC2 of the node VC2 each have a value having the negative temperature characteristic.

The current Ic is generated by applying the voltage VC2 to the variable resistor R2. The variable resistor R2 controls the value of the current Ic. This makes it possible to generate, for each chip, the current Ic as a constant current independent of the process variations. The current Ic generated as described above is represented by

$$Ic = \frac{2}{x β {R}^{2} ( \frac{\sqrt{N}}{\sqrt{N} - 1} )} + \frac{Vth}{xR} \qquad ( 3 )$$

where x is the ratio (R2=xR1) of the variable resistor R1 to the variable resistor R2. As described above, the threshold voltage Vth has the negative temperature characteristic. Therefore, the value of the current Ic generated by the second current generating circuit 20 has the negative temperature characteristic. Thus, the second current generating circuit 20 generates the current Ic having the negative temperature characteristic.

The current synthesizing circuit 30 includes PMOS transistors MP3 and MP4, and an NMOS transistor MN3.

The source of the PMOS transistor MP3 is connected to the power supply. The gate of the PMOS transistor MP3 is connected together with the gates of the PMOS transistors MP1 and MP2 to the node BIASP. That is, the PMOS transistor MP3 forms a current mirror together with the PMOS transistor MP2. The source of the PMOS transistor MP4 is connected to the power supply potential. The gate of the PMOS transistor MP4 is connected together with the gate of the PMOS transistor MP5 to the node BIASC. The drains of the PMOS transistors MP3 and MP4 are connected together to the node VIREF as an output node. The source of the NMOS transistor MN3 is connected to the ground potential. The drain of the NMOS transistor MN3 is connected together with its gate to the node VIREF to form a diode connection.

The current synthesizing circuit 30 operates when the voltage of the node BIASP exceeds the threshold voltage. That is, the PMOS transistor MP3 is turned on when the voltage of the node BIASP exceeds the threshold voltage. Since a current flows through the node VIREF, the potential rises, and the NMOS transistor MN3 is turned on when the potential exceeds the threshold voltage. In this state, the second current generating circuit 20 operates when the voltage of the node VIREF exceeds the threshold voltage as described above, so the voltage of the node BIASC exceeds the threshold voltage. This turns on the PMOS transistor MP4. Thus, a current flows through each transistor and each node.

As described previously, the PMOS transistor MP3 forms a current mirror together with the PMOS transistor MP2. Accordingly, the current Ip equal to that of the PMOS transistor MP2 flows through the PMOS transistor MP3. Note that the number of PMOS transistors MP3 (the number of transistors connected in parallel) is equal to those of PMOS transistors MP1 and MP2 in FIG. 1, but the former need not be equal to the latter and is suitably changed in accordance with the addition ratio to the current Ic (to be described later).

On the other hand, the gate of the PMOS transistor MP4 is connected together with the gate of the PMOS transistor MP5 to the node BIASC. Therefore, the current Ic equal to that of the PMOS transistor MP5 flows through the PMOS transistor MP4. The current Ic flowing through the PMOS transistor MP4 will be explained in detail below.

In the differential amplifier 21, the PMOS transistors MP6 and MP7 form a current mirror. Accordingly, equal currents flow through the PMOS transistor MP6 and NMOS transistor MN4, and through the PMOS transistor MP7 and NMOS transistor MN5. If the PMOS transistors MP6 and MP7 have the same size, therefore, the PMOS transistors MP6 and MP7 have the same gate-to-source potential and the same drain-to-source potential in an equilibrium state.

That is, all of the gate and drain of the PMOS transistor MP6, the gate and drain of the PMOS transistor MP7, the gate of the PMOS transistor MP5, and the gate of the PMOS transistor MP4 have the same voltage. Thus, the PMOS transistors MP4, MP5, MP6, and MP7 form a pseudo current mirror. Since the circuit is configured as described above, the current Ic generated in the PMOS transistor MP5 can be supplied (mirrored) to the PMOS transistor MP4.

Note that the number of PMOS transistors MP4 is equal to that of PMOS transistors MP5 in FIG. 1, but the former need not be equal to the latter and is suitably changed in accordance with the addition ratio to the current Ip.

By connecting the drains of the PMOS transistors MP3 and MP4 together to the drain of the NMOS transistor MN3, a current IREF generated by adding the currents Ip and Ic can be supplied to the NMOS transistor MN3, and the voltage VIREF can be output. The current IREF thus generated is represented by

$$IREF = Ip + Ic = \frac{1}{β {R}^{2}} \{ \frac{2}{x ( \frac{\sqrt{N}}{\sqrt{N} - 1} )} + \frac{2}{{( \frac{\sqrt{N}}{\sqrt{N} - 1} )}^{2}} \} + \frac{Vth}{xR} \qquad ( 4 )$$

As represented by equation (4), the current IREF includes a term having the positive temperature characteristic and a term having the negative temperature characteristic. As described above, the addition ratio of the current Ip to the current Ic can be changed by adjusting the ratio of the number (size) of PMOS transistors MP3 to that of PMOS transistors MP4 (by adjusting the mirror current ratio). Also, it is possible to adjust the value of the current Ip by the number of NMOS transistors MN2 (the ratio to the number of NMOS transistors MN1) and the variable resistor R1, and the value of the current Ic by the variable resistor R2. That is, the temperature characteristic of the current IREF can be set to zero (the dependence on the temperature can be eliminated) by properly adjusting the resistance ratio x, the number of NMOS transistors MN2, or the mirror current ratio.

### [Effects of First Embodiment]

In the above-mentioned first embodiment, the current source circuit includes the first current generating circuit 10 for generating the constant current Ip having the positive temperature characteristic, the second current generating circuit 20 for generating the constant current Ic having the negative temperature characteristic, and the current synthesizing circuit 30 for generating the constant current IREF having a zero temperature characteristic (independent of the temperature) by adding the two constant currents described above. Accordingly, the following effects can be obtained.

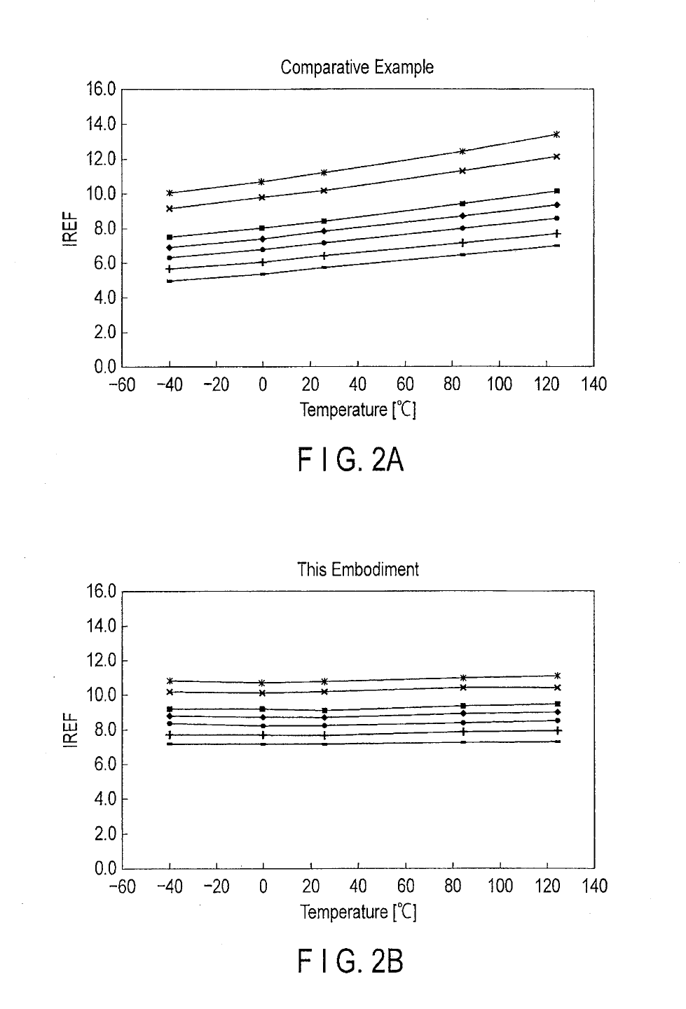

FIG. 2A is a graph showing the relationship between the constant current value and temperature characteristic in a current source circuit according to a comparative example. FIG. 2B is a graph showing the relationship between the constant current value and temperature characteristic in the current source circuit according to the first embodiment. Referring to FIGS. 2A and 2B, the abscissa indicates the temperature, the ordinate indicates the constant current value, and a plurality of plots indicate the changes (absolute value shifts) in current value caused by trimming.

As shown in FIG. 2A, the constant current of the current source circuit according to the comparative example has the positive temperature characteristic by which a current increases as the temperature rises. Therefore, the dependence on the temperature remains even when the constant current value is trimmed for each chip. This deteriorates the circuit characteristics of an analog circuit using the constant current because the dependence on the temperature appears in the characteristics. The current source circuit according to this comparative example is a circuit having, e.g., the same configuration as that of the first current generating circuit 10 shown in FIG. 1.

By contrast, as shown in FIG. 2B, the constant current IREF of the current source circuit according to the first embodiment is constant regardless of the temperature. This is so because the positive and negative temperature characteristics are canceled by adding the current Ip having the positive temperature characteristic and the current Ic having the negative temperature characteristic by appropriately adjusting these currents. Thus, the first embodiment can improve the temperature characteristics and performances of various analog circuits by using the current source circuit that generates the constant current IREF independent of the temperature in these analog circuits.

Note that in the example shown in FIG. 2B, the number of NMOS transistors MN2 and the variable resistors R1 and R2 are set such that the temperature characteristic of the current IREF becomes zero. However, the present embodiment is not limited to this, and the current IREF can be adjusted to either the positive or negative temperature characteristic by changing these values.

It is also possible to freely adjust the temperature characteristic of the current IREF by changing the ratio of the number of PMOS transistors MP2 to that of PMOS transistors MP3, and the ratio of the number of PMOS transistors MP4 to that of PMOS transistors MP5 (the mirror current ratio).

Furthermore, the current source circuit according to the first embodiment makes the temperature characteristic variable by connecting the differential amplifier 21 including a current mirror circuit, and connecting the PMOS transistor MP5 and variable resistor R2, to the conventional current source circuit (including only the first current generating circuit 10). That is, since the increase in number of elements is minimum, the increase in circuit area can also be minimized.

### Application Example

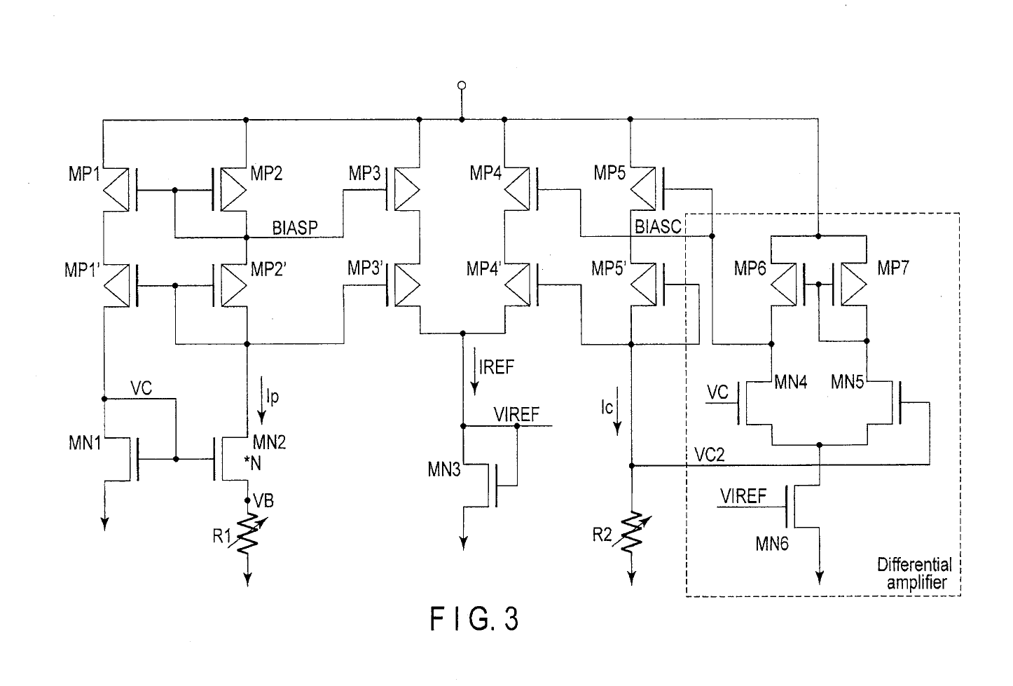

FIG. 3 is a view showing an application example of the current source circuit according to the first embodiment. Note that in this application example, an explanation of the same features as those of the aforementioned first embodiment will be omitted, and different features will be explained.

As shown in FIG. 3, this application example differs from the above-mentioned first embodiment in that PMOS transistors MP1′ to MP5′ are respectively connected in series with the drains of the PMOS transistors MP1 to MP5.

More specifically, the sources of the PMOS transistors MP1′ to MP5′ are respectively connected to the drains of the PMOS transistors MP1 to MP5. The gates of the PMOS transistors MP1′ to MP3′ are connected together to the same node as that of the drain of the NMOS transistor MN2. The gates of the PMOS transistors MP4′ and MP5′ are connected together to the node VC2.

The drain of the PMOS transistor MP1′ is connected to the node VC. The drains of the PMOS transistors MP3′ and MP4′ are connected together to the node VIREF.

The drain of the PMOS transistor MP2′ is connected to the same node as that of its gate, thereby forming a diode connection. That is, the potential difference between one end (the source) and the other end (the drain) of the current path of the PMOS transistor MP2′ is equal to that between one end (the source) of the current path and the gate of the PMOS transistor MP2′. Accordingly, the PMOS transistor MP2′ operates as a pentode. Likewise, the drain of the PMOS transistor MP5′ is connected to the same node (the node VC2) as that of its gate, thereby forming a diode connection. That is, the potential difference between one end (the source) and the other end (the drain) of the current path of the PMOS transistor MP5′ is equal to that between one end (the source) of the current path and the gate of the PMOS transistor MP5′. Accordingly, the PMOS transistor MP5′ operates as a pentode.

The PMOS transistors MP1′ to MP3′ are turned on when the potential of the common node connected to their gates exceeds the threshold voltage. The PMOS transistors MP4′ and MP5′ are turned on when the voltage of the node VC2 exceeds the threshold voltage. At the same time, the NMOS transistor MN5 is turned on.

By respectively connecting the PMOS transistors MP1′ to MP5′ in series with the PMOS transistors MP1 to MP5, it is possible to suppress the dependence of the whole circuit on the power supply voltage, and improve the reliability of the circuit operation.

### Second Embodiment

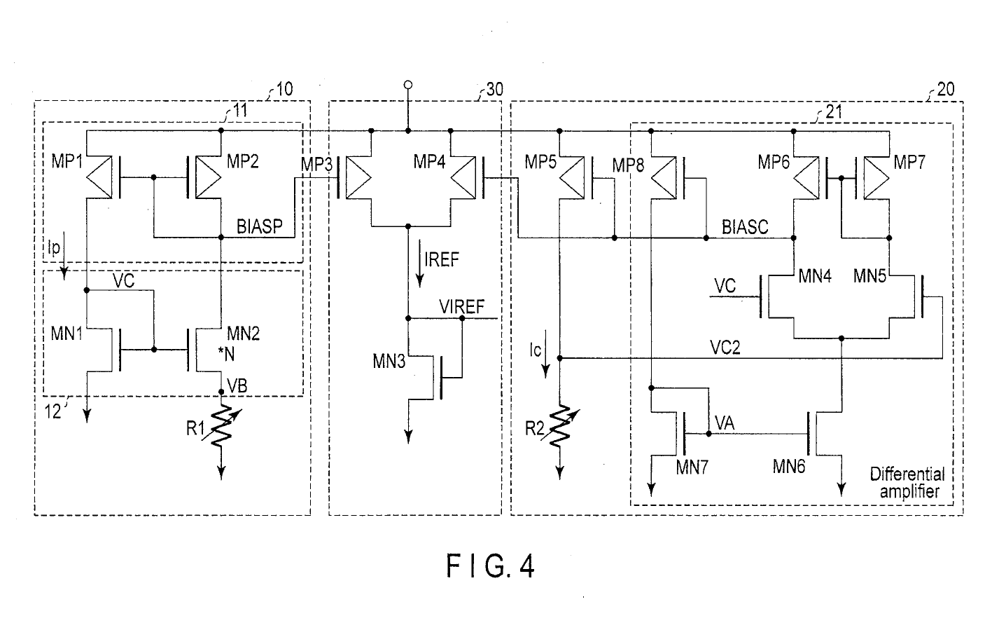

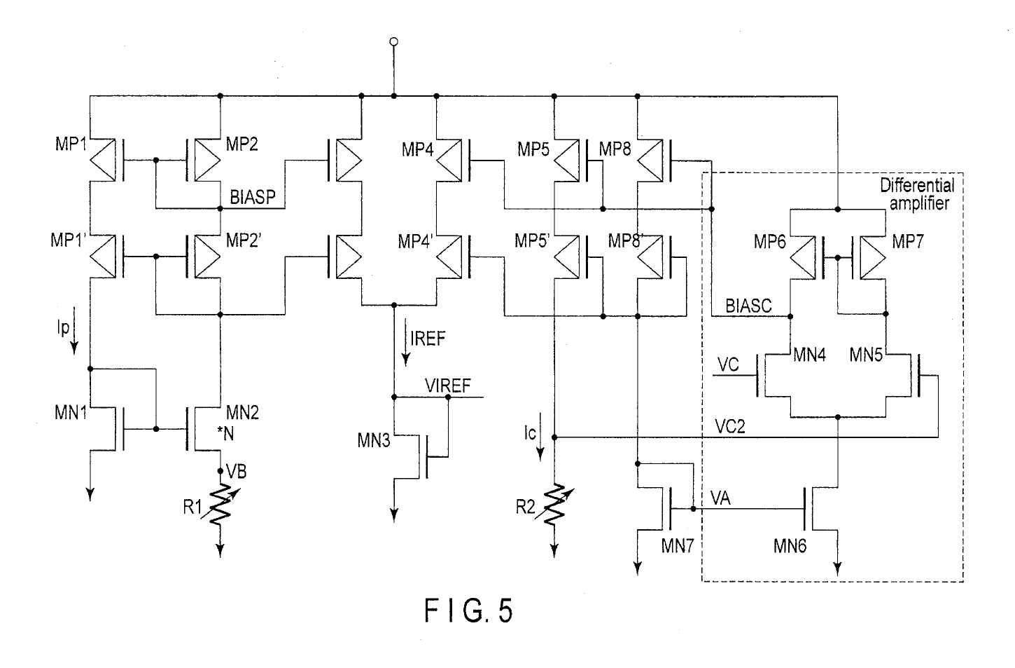

A semiconductor integrated circuit according to the second embodiment will be explained below with reference to FIGS. 4 and 5. The second embodiment is a modification of the first embodiment, in which the operating current of a differential amplifier 21 is determined by inputting a signal different from that of the first embodiment to the gate of an NMOS transistor MN6 forming the differential amplifier 21. Note that in the second embodiment, an explanation of the same features as those of the aforementioned first embodiment will be omitted, and different features will be explained.

### [Circuit Configuration and Operation]

FIG. 4 is a view showing a configuration example of a current source circuit according to the second embodiment.

As shown in FIG. 4, the second embodiment differs from the above-mentioned first embodiment in that a second current generating circuit 20 includes a PMOS transistor MP8 and NMOS transistor NM7.

More specifically, the PMOS transistor MP8 has a source connected to the power supply, and a gate connected to a node BIASC. The drain of the PMOS transistor MP8 is connected to a node VA. The drain of the NMOS transistor MN7 is connected together with its gate to the node VA, thereby forming a diode connection. The source of the NMOS transistor MN7 is grounded. That is, the current paths of the PMOS transistor MP8 and NMOS transistor MN7 are connected in series between the power supply potential and ground potential. The gate of an NMOS transistor MN6 is connected together with the gate (and drain) of the NMOS transistor MN7 to the node VA.

The differential amplifier 21 operates when the voltage of a node VC exceeds a threshold voltage. That is, when the voltage of the node VC exceeds the threshold voltage, a current flows through each transistor and each node of the differential amplifier 21. In this state, the operating current of the differential amplifier 21 is determined by applying a voltage VA of the node VA to the gate of the NMOS transistor MN6. Also, the node VA is biased by turning on the PMOS transistor MP8 having a gate connected to the node BIASC.

### [Effects of Second Embodiment]

The second embodiment described above can achieve the same effects as those of the first embodiment.

### Application Example

FIG. 5 is a view showing an application example of the current source circuit according to the second embodiment. Note that in this application example, an explanation of the same features as those of the aforesaid second embodiment will be omitted, and different features will be explained.

As shown in FIG. 5, this application example differs from the above-described second embodiment in that PMOS transistors MP1′ to MP5′ and MP8′ are respectively connected in series with the drains of PMOS transistors MP1 to MP5 and the PMOS transistor MP8.

More specifically, the sources of the PMOS transistors MP1′ to MP5′ and MP8′ are respectively connected to the drains of the PMOS transistors MP1 to MP5 and MP8. The gates of the PMOS transistors MP1′ to MP3′ are connected together to the same node as that of the drain of an NMOS transistor MN2. The gates of the PMOS transistors MP4′, MP5′, and MP8′ are connected together to the node VA.

The drain of the PMOS transistor MP1′ is connected to the node VC. The drains of the PMOS transistors MP3′ and MP4′ are connected together to a node VIREF. The drain of the PMOS transistor MP5′ is connected to a node VC2.

On the other hand, the drain of the PMOS transistor MP2′ is connected to the same node as that of its gate, thereby forming a diode connection. Similarly, the drain of the PMOS transistor MP8′ is connected to the same node (the node VA) as that of its gate, thereby forming a diode connection. That is, the potential difference between one end (the source) and the other end (the drain) of the current path of the PMOS transistor MP8′ is equal to that between one end (the source) of the current path and the gate of the PMOS transistor MP8′. Accordingly, the PMOS transistor MP8′ operates as a pentode.

The PMOS transistors MP1′ to MP3′ are turned on when the voltage of the common node connected to their gates exceeds a threshold voltage. The PMOS transistors MP4′, MP5′, and MP8′ are turned on when the voltage of the node VA exceeds a threshold voltage. At the same time, the NMOS transistors MN6 and MN7 are turned on.

By respectively connecting the PMOS transistors MP1′ to MP5′ and MP8′ in series with the PMOS transistors MP1 to MP5 and MP8, it is possible to suppress the dependence of the whole circuit on the power supply voltage, and improve the reliability of the circuit operation.

### Third Embodiment

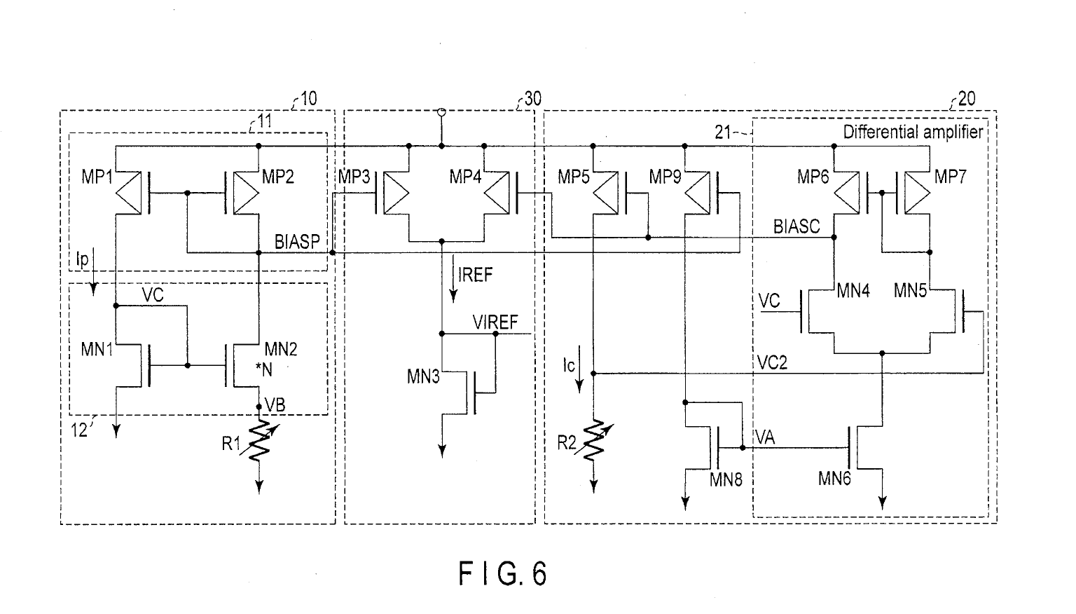

A semiconductor integrated circuit according to the third embodiment will be explained below with reference to FIG. 6. The third embodiment is a modification of the first embodiment, in which the operating current of a differential amplifier 21 is determined by inputting a signal different from that of the first embodiment to the gate of an NMOS transistor MN6 forming the differential amplifier 21. Note that in the third embodiment, an explanation of the same features as those of the above-mentioned first embodiment will be omitted, and different features will be explained.

### [Circuit Configuration and Operation]

FIG. 6 is a view showing a configuration example of a current source circuit according to the third embodiment.

As shown in FIG. 6, the third embodiment differs from the aforementioned first embodiment in that a second current generating circuit 20 includes a PMOS transistor MP9 and NMOS transistor MN8.

More specifically, the PMOS transistor MP9 has a source connected to the power supply, and a gate connected to a node BIASP. The drain of the PMOS transistor MP9 is connected to a node VA. The drain of the NMOS transistor MN8 is connected together with its gate to the node VA, thereby forming a diode connection. The source of the NMOS transistor MN8 is grounded. That is, the current paths of the PMOS transistor MP9 and NMOS transistor MN8 are connected in series between the power supply potential and ground potential. The gate of an NMOS transistor MN6 is connected together with the gate (and drain) of the NMOS transistor MN8 to the node VA.

The differential amplifier 21 operates when the voltage of a node VC exceeds a threshold voltage. That is, when the voltage of the node VC exceeds the threshold voltage, a current flows through each transistor and each node of the differential amplifier 21. In this state, the operating current of the differential amplifier 21 is determined by inputting a voltage VA of the node VA to the gate of the NMOS transistor MN6. Also, the node VA is biased by turning on a PMOS transistor MP9 having a gate connected to the node BIASP.

### [Effects of Third Embodiment]

The third embodiment described above can achieve the same effects as those of the first embodiment.

### Fourth Embodiment

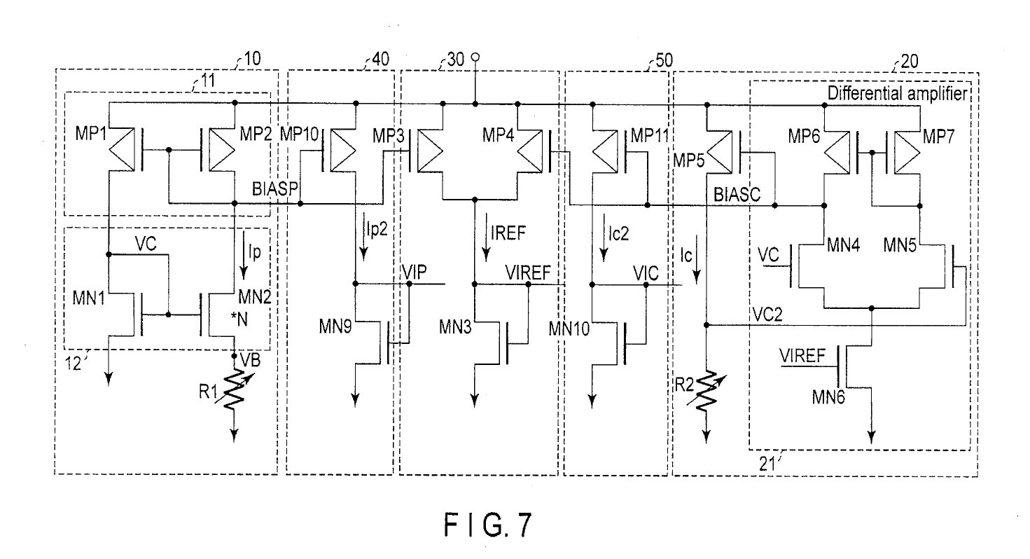

A semiconductor integrated circuit according to the fourth embodiment will be explained below with reference to FIG. 7. The fourth embodiment is a modification of the first embodiment, in which the circuit includes a third current generating circuit 40 and fourth current generating circuit 50. Note that in the fourth embodiment, an explanation of the same features as those of the aforesaid first embodiment will be omitted, and different features will be explained.

### [Circuit Configuration and Operation]

FIG. 7 is a view showing a configuration example of a current source circuit according to the fourth embodiment.

As shown in FIG. 7, the fourth embodiment differs from the above-described first embodiment in that the circuit includes the third current generating circuit 40 for generating a constant current Ip2, and the fourth current generating circuit 50 for generating a constant current Ic2.

The third current generating circuit 40 includes a PMOS transistor MP10 and NMOS transistor MN9. More specifically, the PMOS transistor MP10 has a source connected to the power supply, and a gate connected together with the gates of PMOS transistors MP1 and MP2 to a node BIASP. That is, the PMOS transistor MP10 forms a current mirror together with the PMOS transistor MP2. The drain of the PMOS transistor MP10 is connected to a node VIP as an output node. The drain of the NMOS transistor MN9 is connected together with its gate to the node VIP, thereby forming a diode connection. The source of the NMOS transistor MN9 is connected to the ground potential. That is, the current paths of the PMOS transistor MP10 and NMOS transistor MN9 are connected in series between the power supply potential and ground potential.

The third current generating circuit 40 operates when the voltage of the node BIASP exceeds a threshold voltage. That is, the PMOS transistor MP10 is turned on when the voltage of the node BIASP exceeds the threshold voltage. Consequently, the node VIP is biased, and the NMOS transistor MN9 is turned on. Thus, a current flows through each transistor and each node.

As described above, the PMOS transistor MP10 forms the current mirror together with the PMOS transistor MP2. Therefore, the constant current Ip2 equal to a current Ip of the PMOS transistor MP2 flows through the PMOS transistor MP10, and a voltage VIP is output. That is, the current Ip2 has the same positive temperature characteristic as that of the current Ip. The value of the current Ip2 can be adjusted by adjusting the number (size) of NMOS transistors MN9.

The fourth current generating circuit 50 includes a PMOS transistor MP11 and NMOS transistor MN10. More specifically, the PMOS transistor MP11 has a source connected to the power supply, and a gate connected together with the gate of a PMOS transistor MP5 to a node BIASC. The drain of the PMOS transistor MP11 is connected to a node VIC as an output node. The drain of the NMOS transistor MN10 is connected together with its gate to the node VIC, thereby forming a diode connection. The source of the NMOS transistor MN10 is grounded. That is, the current paths of the PMOS transistor MP11 and NMOS transistor MN10 are connected in series between the power supply potential and ground potential.

The fourth current generating circuit 50 operates when the voltage of the node BIASC exceeds a threshold voltage. That is, the PMOS transistor MP11 is turned on when the voltage of the node BIASC exceeds the threshold voltage. Consequently, the node VIC is biased, and the NMOS transistor MN10 is turned on. Thus, a current flows through each transistor and each node.

The gate of the PMOS transistor MP11 is connected together with the gate of the PMOS transistor MP5 to the node BIASC. Therefore, the constant current Ic2 equal to a current Ic of the PMOS transistor MP5 flows through the PMOS transistor MP11, and a voltage VIC is output. That is, the current Ic2 has the same negative temperature characteristic as that of the current Ic. The value of the current Ic2 can be adjusted by adjusting the number (size) of NMOS transistors MN10.

### [Effects of Fourth Embodiment]

The fourth embodiment described above can achieve the same effects as those of the first embodiment.

In addition, the fourth embodiment includes, as independent circuits, the third current generating circuit 40 for generating the current Ip2 having the positive temperature characteristic, and the fourth current generating circuit 50 for generating the current Ic2 having the negative temperature characteristic. This makes it possible to simultaneously use the current Ip2 as a constant current having the positive temperature characteristic and the current Ic2 as a constant current having the negative temperature characteristic, in addition to a current IREF having a zero temperature characteristic. That is, these constant currents can selectively be used in accordance with the temperature characteristics of individual parts of an analog circuit using the current source circuit.

Note that it is also possible to appropriately change the temperature characteristics of the currents Ip2 and Ic2. For example, a PMOS transistor MP10′ (not shown) is installed in the third current generating circuit 40. The PMOS transistor MP10′ has a source connected to the power supply potential, a gate connected to the node BIASC, and a drain connected to the drain of the PMOS transistor MP10. That is, since the gate is connected to the node BIASC, a current having the negative temperature characteristic flows through the PMOS transistor MP10′. The temperature characteristic of the constant current Ip2 can suitably be set by adjusting the ratio of the number of PMOS transistors MP10 to that of PMOS transistors MP10′.

### <Analog Circuit>

An analog circuit using the constant current source according to each embodiment described above will be explained below.

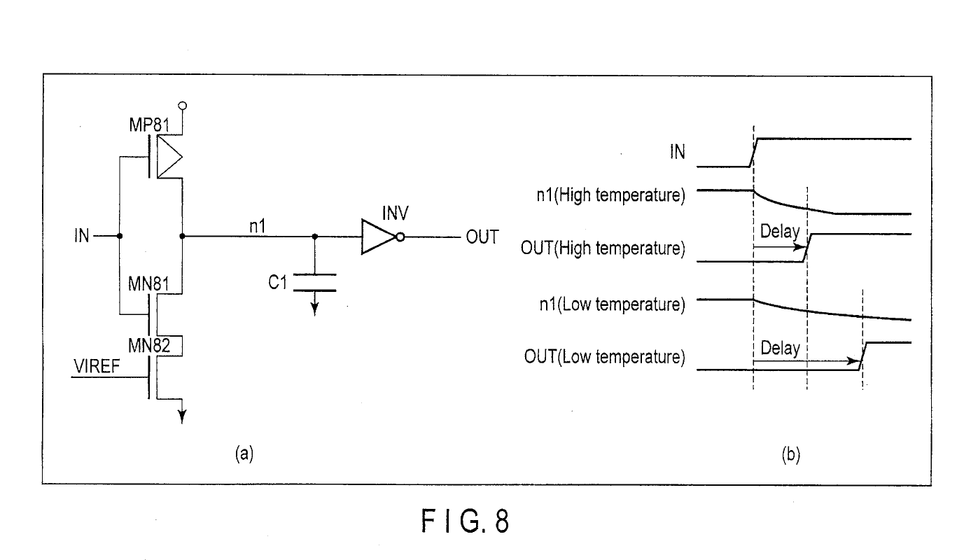

FIG. 8A is a view showing the arrangement of a delay circuit using the constant current source according to each embodiment described above.

As shown in FIG. 8A, this delay circuit includes a PMOS transistor MP81, NMOS transistors MN81 and MN82, a capacitor C1, and an inverter INV. VIREF from the current source circuit is applied to the gate of the NMOS transistor MN82. That is, the NMOS transistor 82 forms a current mirror circuit together with the NMOS transistor MN3.

When an input signal IN is “L”, the PMOS transistor MP81 is turned on, and a node n1 is charged (boosted) to the power supply potential. The capacitor C1 stores the charged (boosted) electricity. In this state, the NMOS transistor 81 is kept OFF.

When the input signal IN changes to “H”, the NMOS transistor MN81 is turned off, and the PMOS transistor MP81 is turned on. In this state, an output signal can be generated by delaying the leading edge of the input signal by a predetermined time by discharging the electricity charged in the node n1 by the constant current of the NMOS transistor MN82.

If, however, the constant current has a temperature characteristic as in the conventional current source circuit, the delay time of the delay circuit similarly depends on the temperature. For example, as shown in FIG. 8B, the delay time of the delay circuit at a low temperature is longer than that at a high temperature.

This problem can be solved by using the temperature-independent constant current (constant voltage) generated by the current source circuit according to this embodiment.

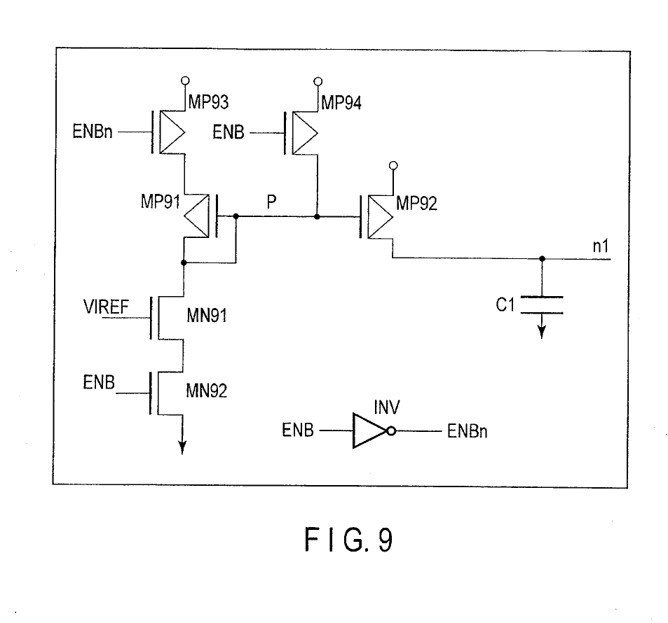

FIG. 9 is a view showing the arrangement of a charging circuit using the constant current source according to each embodiment described above.

As shown in FIG. 9, this charging circuit includes PMOS transistors MP91, MP92, MP93, and MP94, NMOS transistors MN91 and MN92, and a capacitor C1. VIREF from the current source circuit is applied to the gate of the NMOS transistor MN91. That is, the NMOS transistor MN91 forms a current mirror together with the NMOS transistor MN3. This charging circuit charges a specific node (e.g., a bit line BL of a NAND flash memory).

A signal ENB controls the charging circuit. When the signal ENB is “L”, the PMOS transistor MP94 is turned on, and the NMOS transistor MN92 and PMOS transistor MP93 are turned off. Since a node P is charged, therefore, the PMOS transistor MP92 is also turned off, and the circuit operation stops.

When the signal ENB changes to “H”, the PMOS transistor MP94 is turned off, and the NMOS transistor MN92 and PMOS transistor MP93 are turned on. Consequently, a constant current flows through the PMOS transistor MP91, and the capacitor C1 is charged by this constant current by supplying the constant current from the PMOS transistor MP91 to the PMOS transistor MP92 by a current mirror. Since the capacitor is charged with the constant current, the charging time can be made constant, and the peak current can also be suppressed.

Even in this analog circuit example, however, if the constant current has a temperature characteristic, the charging speed and peak current value also depend on the temperature.

This problem can be solved by using the temperature-independent constant current (constant voltage) generated by the current source circuit according to this embodiment.

Although not shown, the constant current source according to each embodiment described above can also be used in analog circuits such as a clock generator and differential amplifier.

The clock generator can generate a clock having a predetermined period by using a constant current and constant voltage. However, the clock period becomes temperature-dependent if the constant current and constant voltage used are temperature-dependent.

Also, when the differential amplifier is operated by applying a constant voltage as the output from the constant current source as a bias current, it is possible to always hold the operating current of the amplifier constant and hold the operating speed and operation margin constant. Even in this case, however, if the input constant voltage fluctuates due to the temperature, the current flowing through the amplifier also has a temperature characteristic. This poses problems such as deterioration (a decrease) in operating speed of the amplifier during a low-temperature operation.

Even in these clock generator and differential amplifier, operation errors caused by the dependence on the temperature can be eliminated by using the temperature-independent constant current (constant voltage) generated by the current source circuit according to this embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A current source circuit comprising:
a first current generating circuit which comprises a first current mirror circuit including PMOS transistors, and a second current mirror circuit including NMOS transistors, the first current generating circuit being configured to generate a first current having a positive temperature characteristic;
a second current generating circuit which comprises a feedback circuit configured to receive a first voltage depending on a threshold voltage of the NMOS transistors and having a negative temperature characteristic, and output a second voltage equal to the first voltage, the second current generating circuit being configured to generate a second current having the negative temperature characteristic based on the second voltage; and
a current synthesizing circuit which generates a substantially constant current having an arbitrary temperature characteristic by adding the first current and the second current.

2. The circuit of claim 1, wherein the feedback circuit comprises:
a third current mirror circuit including PMOS transistors;
a first NMOS transistor having a gate to which the first voltage is applied; and
a second NMOS transistor which has a current path having one end connected to one end of a current path of the first NMOS transistor and the other end connected to the third current mirror circuit, and has a gate to which the second voltage is supplied.

3. The circuit of claim 2, wherein
the first current mirror circuit comprises:
a first PMOS transistor having a source connected to a power supply, a gate connected to a first node, and a drain connected to a second node; and
a second PMOS transistor having a source connected to the power supply, and a gate and a drain connected to the first node,
the second current mirror circuit comprises:
a third NMOS transistor having a drain and a gate connected to the second node, and a source connected to a ground potential; and
a fourth NMOS transistor having a drain connected to the first node, a gate connected to the second node, and a source connected to a third node,
the first current generating circuit further comprises a first resistance element connected between the third node and the ground potential, and
the first voltage applied to the feedback circuit is a voltage of the second node.

4. The circuit of claim 3, wherein
the third current mirror circuit comprises:
a third PMOS transistor having a source connected to the power supply, a gate connected to a fourth node, and a drain connected to a fifth node; and
a fourth PMOS transistor having a source connected to the power supply, and a gate and a drain connected to the fourth node,
the first NMOS transistor has a drain connected to the fifth node, a gate connected to the second node, and a source connected to a sixth node, and
the second NMOS transistor has a drain connected to the fourth node, a gate connected to a seventh node having the same voltage as that of the second node, and a source connected to the sixth node.

5. The circuit of claim 4, wherein
the feedback circuit further comprises a fifth NMOS transistor having a drain connected to the sixth node, a gate connected to an eight node as an input node, and a source connected to the ground potential,
the second current generating circuit further comprises:
a fifth PMOS transistor having a source connected to the power supply, a gate connected to the fifth node, and a drain connected to the seventh node; and
a second resistance element connected between the seventh node and the ground potential, and
the current synthesizing circuit forms a current mirror together with the first current generating circuit, and forms a current mirror together with the second current generating circuit, thereby the current synthesizing circuit being configured to generate the constant current by adding the first current and the second current.

6. The circuit of claim 5, wherein
the current synthesizing circuit comprises:
a sixth PMOS transistor having a source connected to the power supply, a gate connected to the first node, and a drain connected to a ninth node;
a seventh PMOS transistor having a source connected to the power supply, a gate connected to the fifth node, and a drain connected to the ninth node; and
a sixth NMOS transistor having a drain and a gate connected to the ninth node, and a source connected to the ground potential.

7. The circuit of claim 5, wherein the first resistance element and the second resistance element are variable resistance elements.

8. The circuit of claim 6, further comprising an eighth PMOS transistor having a current path connected in series with the drain of one of the first PMOS transistor, the second PMOS transistor, the fifth PMOS transistor, the sixth PMOS transistor, and the seventh PMOS transistor.

9. The circuit of claim 5, wherein the second current generating circuit further comprises:
a sixth PMOS transistor having a source connected to the power supply, a gate connected to the fifth node, and a drain connected to the eighth node; and
a sixth NMOS transistor having a drain and a gate connected to the eighth node, and a source connected to the ground potential.

10. The circuit of claim 5, wherein the second current generating circuit further comprises:
a sixth PMOS transistor having a source connected to the power supply, a gate connected to the first node, and a drain connected to the eighth node; and
a sixth NMOS transistor having a drain and a gate connected to the eighth node, and a source connected to the ground potential.

11. The circuit of claim 5, further comprising:
a third current generating circuit which comprises a sixth PMOS transistor having a source connected to the power supply, a gate connected to the first node, and a drain connected to a ninth node, and a sixth NMOS transistor having a source connected to the ground potential, and a gate and a drain connected to the ninth node, and generates a constant current having the positive temperature characteristic; and
a fourth current generating circuit which comprises a seventh PMOS transistor having a source connected to the power supply, a gate connected to the fifth node, and a drain connected to a tenth node, and a seventh NMOS transistor having a source connected to the ground potential, and a gate and a drain connected to the tenth node, and generates a constant current having the negative temperature characteristic.

12. The circuit of claim 1, further comprising:
a third current generating circuit which generates a constant current equal to the first current and having the positive temperature characteristic; and
a fourth current generating circuit which generates a constant current equal to the second current and having the negative temperature characteristic.
